(19) United States
(12) Patent Application Publication
(10) Pub. No.: US 2025/0112123 A1
(43) Pub. Date: Apr. 3, 2025

(54) THROUGH SUBSTRATE VIA STRUCTURES AND PROCESSES

(71) Applicant: ADEIA SEMICONDUCTOR BONDING TECHNOLOGIES INC., San Jose, CA (US)

(72) Inventors: Rajesh Katkar, Milpitas, CA (US); Cyprian Emeka Uzoh, San Jose, CA (US)

(21) Appl. No.: 18/515,964

(22) Filed: Nov. 21, 2023

Related U.S. Application Data
(60) Provisional application No. 63/587,010, filed on Sep. 29, 2023.

(51) Int. Cl. H01L 23/48; H01L 21/768; H01L 23/00; H01L 25/065

(52) U.S. Cl. CPC H01L 23/481; H01L 21/76898; H01L 24/05; H01L 24/13; H01L 25/0657; H01L 2224/0557; H01L 2224/05647; H01L 2224/13147; H01L 2225/06544; H01L 2924/10253

(57) ABSTRACT

Disclosed is a microelectronic structure including a first element and a through substrate via (TSV) structure. The first element includes a bulk portion having a front side and a back side opposite the front side. The TSV structure is disposed in an opening extending at least partially through the bulk portion from the front side to the back side. The TSV structure includes a conductive tip portion and a second conductive via portion. The second conductive via portion is disposed between the front side and the conductive tip portion. The conductive tip portion contains a different conductive material than the second conductive via portion.

### INCORPORATION BY REFERENCE TO ANY PRIORITY APPLICATIONS

This application claims priority to U.S. provisional patent application No. 63/587,010, filed on Sep. 29, 2023, the disclosure of which is incorporated by reference herein in its entirety.

### FIELD

The field relates to structures with through-substrate vias and methods for forming the same.

### BACKGROUND

Semiconductor elements, such as integrated device dies or chips, may be mounted or stacked on other elements. For example, a semiconductor element can be mounted to a carrier, such as a package substrate, an interposer, a reconstituted wafer or element, or other semiconductor element. As another example, a semiconductor element can be stacked on top of another semiconductor element, e.g., a first integrated device die can be stacked on a second integrated device die. In some arrangements, a through-substrate via (TSV) can extend vertically through a thickness of the semiconductor element to transfer electrical signals through the semiconductor element, e.g., from a first surface of the semiconductor element to a second opposing surface of the semiconductor element. There is a continuing need for improved methods of forming TSVs.

### BRIEF DESCRIPTION OF THE DRAWINGS

For this discussion, the devices and systems illustrated in the figures are shown as having a multiplicity of components. Various implementations of devices and/or systems, as described herein, may include fewer components and remain within the scope of the disclosure. Alternatively, other implementations of devices and/or systems may include additional components, or various combinations of the described components, and remain within the scope of the disclosure.

These aspects and others will be apparent from the following description of preferred embodiments and the accompanying drawings, which are meant to illustrate and not to limit the invention, wherein:

FIG. 1A is a schematic side sectional view of two elements before being hybrid bonded, according to an embodiment.

FIG. 1B is a schematic side sectional view of the two elements of FIG. 1A after being hybrid bonded, according to an embodiment.

FIGS. 2A-2G are a series of schematic side sectional views that show a method by which a first element of a microelectronic structure can be formed to have via structures with conductive tips of a different material from the remainder of TSVs prior to revealing the back side, according to an embodiment.

FIG. 2H is a schematic side sectional view of the microelectronic structure in which the first element shown in FIG. 2G is hybrid bonded to a second element having a similar TSV structure, according to an embodiment.

FIGS. 3A-3D are a series of schematic side sectional views that show a method by which the first element of FIG. 2G can be further processed to provide bonding pads over the conductive tips, according to an embodiment.

FIGS. 4A is a schematic side sectional view of a microelectronic structure similar to FIG. 2G, with a redistribution layer formed over the side with the conductive tips, according to an embodiment.

FIG. 4B is a schematic side sectional view of a microelectronic structure similar to the one presented in FIG. 2G, with bonding pads formed over the back side of the conductive tips, where the bonding pads are wider than the conductive tips, according to an embodiment.

FIG. 4C is a schematic side sectional view of a microelectronic structure similar to FIG. 4B hybrid bonded to second microelectronic element having a similar TSV structure.

FIGS. 5A-5D are a series of schematic side sectional views that show a method by which a microelectronic structure similar to that of FIG. 2G is provided with a sacrificial tip material prior to being revealed, where the sacrificial tip material is subsequently replaced to form a conductive tip, according to an embodiment.

FIG. 5E is a schematic side sectional view of the microelectronic structure in which the first element shown in FIG. 5D is hybrid bonded to a second element having a similar TSV structure, according to an embodiment.

FIG. 6 is a schematic side section view of a microelectronic structure similar to the one presented in FIG. 2G, where the conductive tip comprises solder, according to an embodiment.

FIGS. 7A-7C present schematic side sectional views of microelectronic structures, similar to the ones presented in in the foregoing embodiments, bonded by conventional means to second microelectronic elements in various configurations, according to some embodiments.

### DETAILED DESCRIPTION OF PREFERRED EMBODIMENTS

Embodiments described herein facilitate hybrid bonding on the back sides of substrates having through substrate vias (TSVs). Novel techniques are taught for providing TSVs that includes forming a staged TSV of multiple materials that provide advantages in preparation for hybrid bonding. In some embodiments, deep vias formed from the front side of the substrate are only partially filled with a first material, such as by using a bottom-up deposition technique or by filling and recessing. The remainder of the vias are filled with a second material. The first material is revealed first when thinning the substrate from the back side. The back side can then be prepared for hybrid bonding. In some embodiments, the first material remains part of the TSV at the back side. In some embodiments, the first material is directly bonded to conductors of another element in a hybrid bonding process. In other embodiments, a pad is provided to intervene between the first material of the TSV and the conductors of the other element. In still other embodiments, the first material is a sacrificial material that is replaced by suitable conductive material prior to hybrid bonding.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one clement to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 108a and/or 108b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both clements, and is subject to reversal by reheating. By way of contrast, direct metal bonding as employed in hybrid bonding does not require melting or an intermediate fusible metal alloy. and can result in strong mechanical and electrical connections, often demonstrating interdiffusion of the bonded conductive features with grain growth across the bonding interface between the elements, even without the much higher temperatures and pressures of thermocompression bonding.

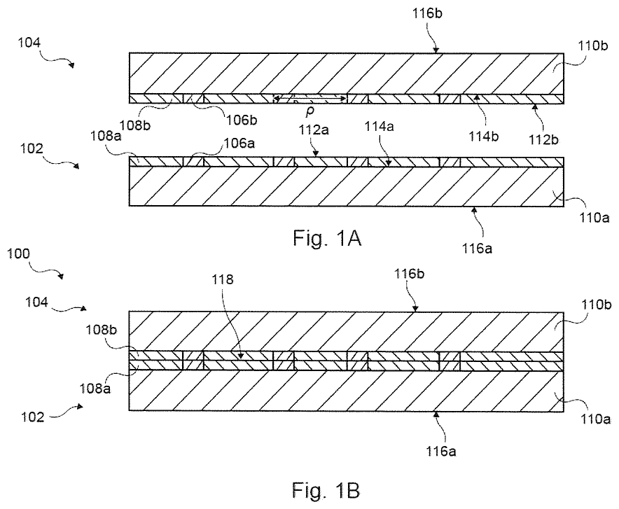

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C. 5 ppm/° C. to 40 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third clement, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially crodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one clement migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 106a, 106b across the direct bond interface 118 (e.g., small or fine pitches for regular arrays).

In some embodiments, a pitch p of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

Embodiments taught herein involve TSVs for back side hybrid bonding. TSVs can be formed by many different methods, including via-first, via-middle, or via-last techniques. In via-first or via-middle processes, relatively deep (e.g., multiple microns in depth) blind openings are opened from the front side of the substrate, such as by reactive ion etching (RIE) or laser drilling. The substrate can be a bulk semiconductor material (e.g., silicon, III-V materials) with active devices, but in other embodiments the substrate can be glass or ceramic, particularly for passive elements like interposers or carrier substrates. For active element embodiments, the front side of the substrate typically includes devices, such as transistors, and metallization layers referred to as back-end-of-line (BEOL) layers, which can be formed before or more typically after defining the TSV structures. For example, in via middle process, transistors are formed via high temperature front end process, after which, blind TSVs are formed, followed by multi layers of metallization or BEOL layers. The blind openings are filled with conductive material, typically predominantly copper due to its high conductivity. At this stage the vias can be considered buried, blind, or embedded TSVs which do not actually extend all the way to the back side of the substrate, as the substrate has not yet been thinned to its final thickness. Subsequently the substrate (e.g., bulk semiconductor material) is thinned from the back side to reveal the back sides of the conductive material, and effectively form the TSVs extending from the front side of the substrate to the back side of the thinned substrate.

One problem with traditional via-first or via-middle TSVs is that, due to the great depth that the openings are etched into the bulk substrate material, the openings tend not to have identical depths, and there can be a great deal of variation in pre-reveal TSV depth across the substrate. For example, TSV formed near the center of the wafer may have different depths than those near the edge of the wafer. When revealing the TSVs from the back side (for e.g. using back side thinning of the wafer followed by dry or wet etch to expose the bottom tips of the TSVs), the consequent variation in height means that the deeper TSVs will be revealed first as the substrate is thinned from the back side, and continued thinning in order to reveal the shallower TSVs can cause problems, such as smearing the conductive material across the substrate, substrate contamination due to longer exposure to the conductive material which may diffuse into the substrate, breakage of some of the deeper TSVs, and wearing away of some of the barrier materials that protect the conductive TSVs. Any smearing of copper from TSVs during thinning, grinding or CMP may contaminate the adjacent silicon substrate, and should be avoided. Embodiments taught herein can alleviate some of the problems introduced during back side reveal and subsequent processing by the potential for variable-depth embedded TSVs.

In some embodiments, the TSVs comprise at least two portions: a tip at the back side end of the TSV, and a second conductive portion near the middle or at the frontside end of the TSV. In some embodiments, the material of the conductive tip is different from the material of the second conductive portion of the TSV. In some embodiments, the metal of a conductive tip is different from the metal of the second conductive portion of the TSV. The TSVs can be formed by using bottom-up deposition techniques. Some such techniques are gas-based, but others are wet processing (electroplating or electroless plating).

The tip of the TSV structure can comprise a material that contaminates silicon less than copper does, does not diffuse into silicon at room temperature (or has less diffusivity in silicon than copper), or is less susceptible to smearing across the substrate during chemical mechanical planarization (CMP) compared to copper.

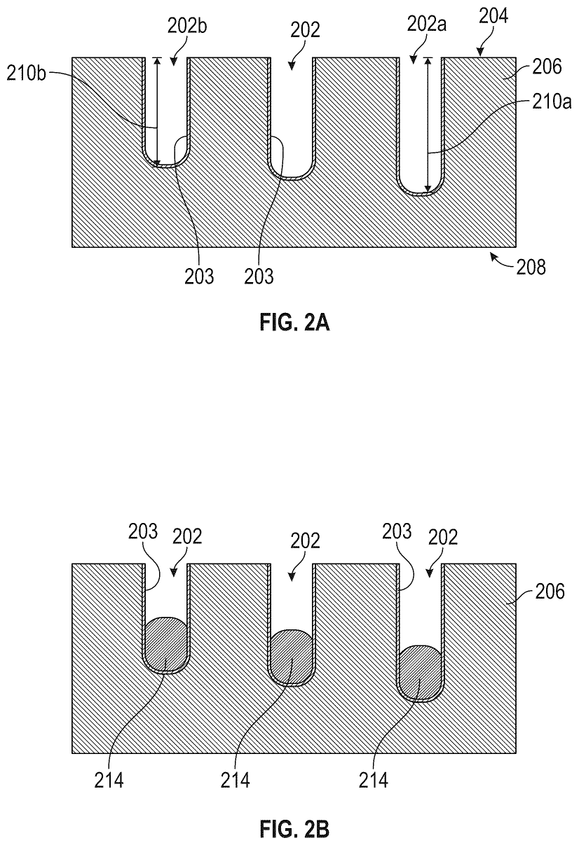

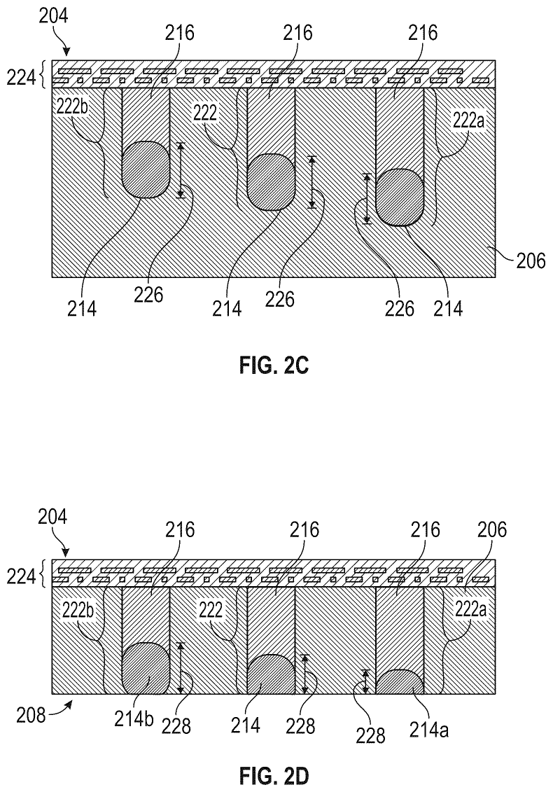

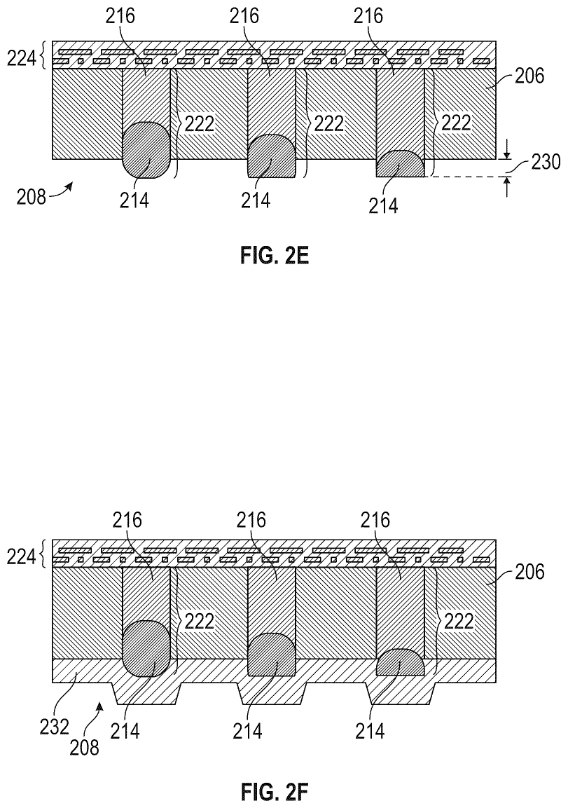

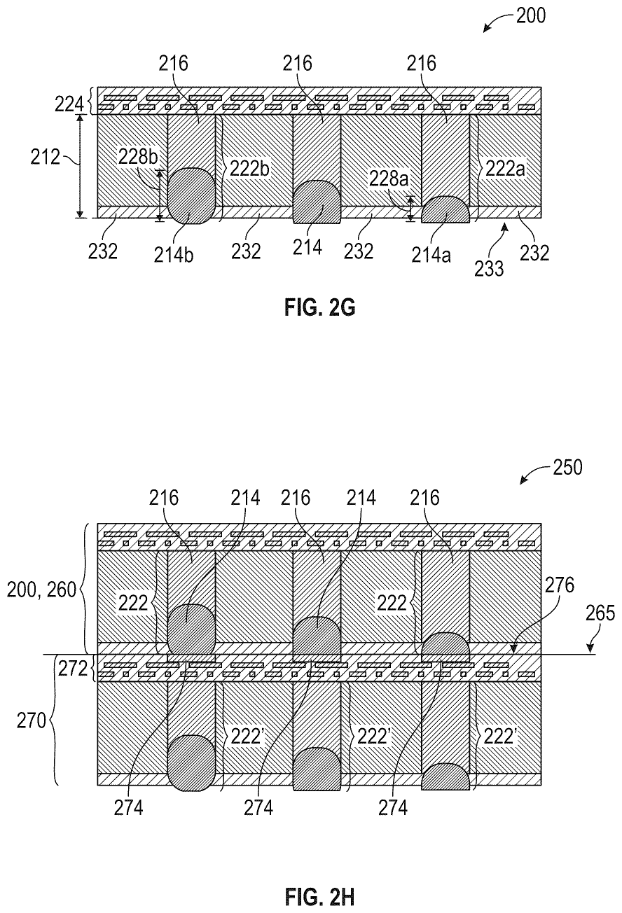

FIGS. 2A-2G schematically present a method of forming the microelectronic structure 200 of FIG. 2G. The method presented is a bottom-up deposition process. FIG. 2A shows a plurality of blind openings 202 formed from the front side 204 of a bulk substrate 206 for forming a first element. The substrate 206 can comprise a wafer of semiconductor material (e.g., silicon, III-V materials, or more exotic compound materials employed for optical devices), or can comprise materials such as glass, ceramic or other suitable materials. The substrate 206 may include active transistors, passive devices, or may act as a carrier, bridge, or an interposer. The blind openings 202 extend from a front side 204 or front surface of the substrate 206 toward a back side 208 or back surface of the substrate 206. In some embodiments, the substrate 206 includes active devices (e.g., transistors) at the front side 204, which can be fabricated before or after forming the TSVs. The blind openings 202 are typically multiple microns in depth 210 and deeper than the intended final (post-thinning) thickness 212 of the element being fabricated (shown in FIG. 2G). For example, an average depth 210 of blind openings 202 may be between 0.5-5 μm, or between 5-50 μm, or between 10-150 μm, or more. In some embodiments, the blind openings 202 can have relatively high non-uniformity, such as up to several microns in depth. Due to the process variations or tool limitations, there can be significant differences in the depths 210 of the blind openings 202. TSV structures of different diameters or widths across the substrate can also contribute to variation in depths 210 of the blind openings 202. The blind openings 202 can be fully or partially lined with at least one of, for example, a dielectric and/or conductive barrier layer 203, and can also be lined with a seed layer for subsequent filling (not shown). The blind openings 202 can be formed by, for example, RIE or laser drilling. In some embodiments, the lateral dimension of blind openings or vias may vary. Within the design or layout of the blind openings, some via lateral dimension, for example, via diameter may be 10% to 40% smaller than their neighbors. For example, the diameter of a first array of vias may be smaller than the diameter of a second array of vias. In practice, after the via forming process, for example by RIE methods, the depth of the smaller vias may be smaller than the depth of the larger vias. In some embodiments the variation in the depth of the vias may range from 3 μm to more than 10 μm. In some embodiments, the larger vias are adapted to supply power or ground or both, and in some embodiments, the smaller vias are adapted for signals.

FIG. 2B shows a tip portion 214 disposed into each of the bottom of the blind openings 202, partially filling the blind openings 202. In the illustrated embodiment, the tip portion 214 comprises an electrically conductive material to form a conductive tip portion 214. In other embodiments, the tip portion can comprise a sacrificial material to form a sacrificial tip portion, which can be conductive or dielectric. Conductive tip portions can compose part of the final structure, while sacrificial tip portions are configured to be removed and replaced during manufacture. Additional details of conductive tip portions and sacrificial tip portions are further discussed below. The illustrated tip portion 214 of FIG. 2B is a conductive tip portion 214, and portions of it remain in the final product. In some embodiments, at least one of the barrier layer 203 or a seed layer (not shown) can be disposed over the tip portion 214. The illustrated structure of FIG. 2B shows the barrier layer 203 lining the blind openings 202. While the barrier layer 203 is not shown in FIGS. 2C-2H, the skilled artisan will appreciate that the barrier layer 203 need not be removed between the stages corresponding to FIGS. 2B and 2C. Rather, in some embodiments (represented by FIGS. 2A and 2B), barrier layers can be included, while in other embodiments (represented by FIGS. 2C-2H), barrier layers can be omitted. In some embodiments, the tip portion may comprise a conformal conductive coating. Some embodiments may further comprise a scam within the conductive coating of the tip portion. In other embodiments, the tip portion may comprise conductive material with voids.

The tip portion (e.g., conductive tip portion 214) can comprise a material that is less subject to smearing across the substrate (e.g., substrate 206) during chemical mechanical planarization (CMP) compared to copper. In some embodiments, the tip portion can also be harder than copper. In some embodiments, a conductive tip portion (e.g., conductive tip portion 214) can be direct bonded to copper without an intervening adhesive, e.g., to a copper pad exposed at the bonding surface of another substrate. In some embodiments, a conductive tip portion can comprise nickel or a nickel alloy. In some embodiments, a conductive tip portion can be predominantly nickel, such as greater that 50 atomic percent nickel, greater than 60 atomic percent nickel, or greater than 90 atomic percent nickel. In some embodiments, a conductive tip portion can comprise cobalt, tungsten, indium, or a suitable alloy. In some other embodiments, a conductive tip portion can comprise a conductive adhesive. In still other embodiments, as described a conductive tip portion can comprise solder. In some other embodiments, a conductive tip portion can also comprise copper with a different impurity concentration or grain structure compared to the conductive second via portion.

The skilled artisan will appreciate that any of multiple techniques can be employed to only partially fill the blind openings 202 with the tip portion (e.g., conductive tip portion 214). For example, gas phase or wet processing (e.g., electroplating or electroless plating) techniques are known for various material for bottom-up filling. In some embodiments, the blind openings can be partially or fully filled with the desired material, and subsequently etched back (e.g., by wet or vapor etching) to leave the tip portion only in the bottom portion of the blind openings.

FIG. 2C shows the remaining portions of the blind openings 202 (shown in FIG. 2B), above the conductive tip portions 214, filled with a conductive second via portion 216, disposed over the tip portion 214. The conductive tip portion 214 and the conductive second via portion 216 together form an embedded TSV structure 222. In some embodiments, a thin layer of another conductive material, such as a conductive barrier material (e.g., Ti, Ta, metal nitrides, etc.) may be deposited on the tip portion before depositing the conductive second via portion. One or more metallization layers 224, e.g., BEOL layers and/or redistribution layers (RDL), are disposed on the front side 204 of the bulk substrate 206. The conductive material deposited in the second via portion 216 is different from the material deposited in the conductive tip portion 214. In some embodiments, the conductive second via portion comprises copper. In some embodiments, the conductive second via portion is predominantly copper, such as greater that 50 atomic percent copper, greater than 60 atomic percent copper, or greater than 90 percent atomic copper. In some embodiments, the second via portion comprises a different material than that of the tip portion. In some embodiments, the second via portion comprises a different metal or alloy than the metal or alloy of the conductive tip portion. In some embodiment, another seed and/or conductive barrier layer and or adhesion layer may be formed on the conductive tip portion before the deposition of the second conductive portion.

FIG. 2D shows the conductive tip portions 214 revealed or exposed from the back side of the plurality of the TSV structures 222. The back side 208 of the bulk substrate 206 can be thinned using, for example, lapping, grinding, etching, CMP, or a combination thereof. It will be understood by a skilled artisan that a TSV structure in a product, as used herein, extends at least to the back side of the bulk portion of the substrate, as thinned, and can also extend to the front side of the bulk portion of the substrate. Typically, a terminal portion of the thinning process to reveal embedded TSV structures includes a planarizing phase such as CMP. As the back side 208 is thinned, the deepest TSV structure 222a (shown in FIG. 2C) is revealed first and the shallowest TSV structure 222b is revealed last. To reveal the shallowest TSV structure 222b (shown in FIG. 2C), the tip portion 214a of the deeper TSV structures (e.g., TSV structure 222a) must also be thinned. At least in part for this reason, the thicknesses 228 of the conductive tip portions 214 (shown in FIG. 2D) vary. In some embodiments, the tip portions (e.g., conductive tip portions 214) have an original thickness 226 (shown in FIG. 2C) within the TSV structure 222 that is greater than (at least 1×, e.g., 1×-5× or 1.1×-2.5×) the difference between the depths 210a, 210b of the deepest blind opening 202a and the shallowest blind opening 202b (shown in FIG. 2A). In other words, even after the tip portion 214a of the deepest TSV structure 222a is thinned to expose the tip portion 214b of the shallowest TSV structure 222b, in some embodiments, no tip portion has been completely thinned away. In other words, in some embodiments, no second via portion (e.g. second conductive via portion 216) of a TSV structure (e.g. TSV structure 222) is revealed at the back side (e.g. back side 208 of thinned substrate 206). Beneficially, the tip portion (whether conductive or sacrificial) can comprise a material that is less subject to smearing during planarization that reveals the tip portions, as compared to copper. In some other embodiments, the mechanical lapping, grinding or polishing process is performed to only reach very close to the deepest TSV structure (e.g. TSV structure 222a), but not expose any tip portion thereof (e.g. tip portion 214a) by lapping, grinding or polishing. The tip (e.g. tip portion 214) is instead exposed via selective etching of the bulk substrate (e.g. substrate 206) to avoid contamination of the substrate by the material at the tip during this mechanical grinding or polishing. Enough material of substrate is then removed by etching so as to reveal or expose the tips of all the TSVs.

FIG. 2E shows the bulk substrate 206 selectively etched, such that the TSV structures 222 protrude on the back side 208 of the substrate 206. In some embodiments, the selective etch is a dry etch, and can be isotropic but is more typically directional. In some embodiments, for example, in which the bulk substrate comprises silicon, RIE employing SF6 can selectively etch the silicon with minimal damage to the selected conductive tip material (e.g., nickel) and any lining barrier materials (e.g. barrier layer 203 shown in FIG. 2A) for the TSV. The material used for the tip portion (whether conductive or sacrificial) can be more resistant to the selective etchant than is the bulk substrate 206. The amount of protrusion 230 can also define a desired thickness for a dielectric layer 232 (e.g. a dielectric bonding layer) to be formed (see FIGS. 2F-2G and description). In some embodiments, the protrusion 230 of TSV structures 222 on the back side 208 of the substrate 206 can be less than 100 nm, less than 10 μm, or between 50 nm and 100 nm, or between 500 nm and 15 μm.

FIG. 2F shows the deposition of one or more dielectric layers 232 over the back side 208 of the substrate 206 and over the back side of the TSV structures 222. The dielectric layer 232 can comprise any of the dielectric bonding materials described above, and can also serve to aid in planarization for subsequent bonding. For example, the dielectric layer 232 can comprise an initial thin silicon nitride layer to serve as a barrier and/or etch stop, and a thicker silicon oxide layer thereover. In some embodiments, a silicon oxide layer is deposited directly over the tip portion (e.g. conductive tip portion 214) and the back side of the bulk semiconductor material. In some other embodiments, thin silicon oxynitride or silicon carbonitride may also be deposited on top of the oxide layer or embedded within the dielectric layer 232. The dielectric layer 232 in some embodiments can comprise layers of inorganic materials and polymeric materials. The polymeric material may comprise, for example, a high temperature epoxide coating. The strong adhesion and lateral mechanical support of the hard polymer layer to the TSV structures can help prevent breakage of the TSV structures during CMP.

FIG. 2G shows the structure of FIG. 2F after being planarized to expose the conductive tip portions 214 of the TSV structures 222. The back side of the microelectronic structure 200 of FIG. 2G can be prepared for hybrid bonding, such as by sufficient planarization and any desired activation and/or termination, as described above. The skilled artisan will appreciate that the surface of the conductive tip portion 214 can be slightly recessed relative to the surface 233 of the dielectric layer 232 surrounding it to facilitate metal bonding in an anneal/expansion phase of hybrid bonding, as described hereinabove. The second conductive via portion 216 and the conductive tip portion 214 of the TSV structures 222 of FIG. 2G can include, and be predominantly formed of, different metals, as described above. Moreover, the relative heights or thicknesses 228a, 228b, and/or diameters, of conductive tip portions 214a, 214b can differ significantly due to design (signal vs. ground or power) or the variation in etch depth noted above. In some embodiments, the heights or thicknesses (e.g., thickness 228b) of conductive tip portions (e.g. conductive tip portion 214) can vary from one TSV structure to another by more than 1%, such as 0.5-25%, 1-10%, by more than 15%, or more than 20%, relative to the thinner of the two conductive tip portions 214a being compared. Similarly, the diameter of the conductive tip portions 214 can vary from one TSV structure to another by more than 1%, such as by 0.5-25%, by 1-10%, by more than 15%, or by more than 20%. These height/thickness differences, such as the difference between the thickness 228b of the thicker conductive tip portion 214b and the thickness 228a of the thinner conductive tip portion 214a in FIG. 2G, can apply to the TSV conductive tip portions of multiple embodiments taught herein, including sacrificial embodiments.

FIG. 2H shows a bonded structure 250, in which the back side of the first clement 260, particularly the first microelectronic structure 200 of FIG. 2G, is hybrid bonded to a bonding layer 272 (e.g., BEOL or RDL layer) on the front side 276 of a second element 270, along a bond interface 265. In some embodiments, the conductive tip portion (e.g., conductive tip portion 214) of the TSV (e.g., TSV structure 222) at the back side of the first element (e.g., first element 260) is directly bonded to a contact pad (e.g., contact pad 274) on the front side or front side (e.g., front side 276) of the second element (e.g., second element 270). In some embodiments, the metal-to-metal bond between contacts of the first and second microelectronic structures is a direct nickel-to-copper bond. In the illustrated embodiment, the second element 270 comprises a second microelectronic structure (e.g., integrated circuit), and also includes TSV structures 222′ similar to those of the first element 260. In other embodiments, the second element need not include TSVs, or can include TSVs formed by other techniques.

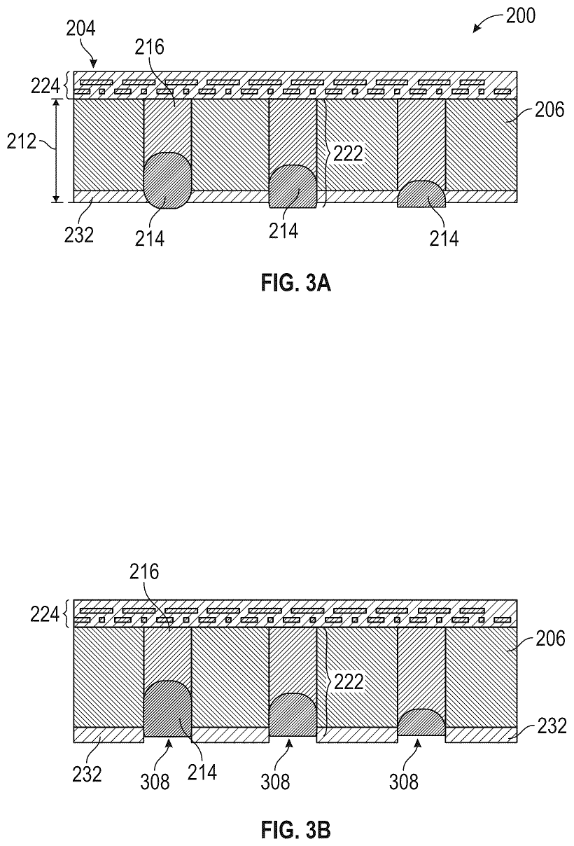

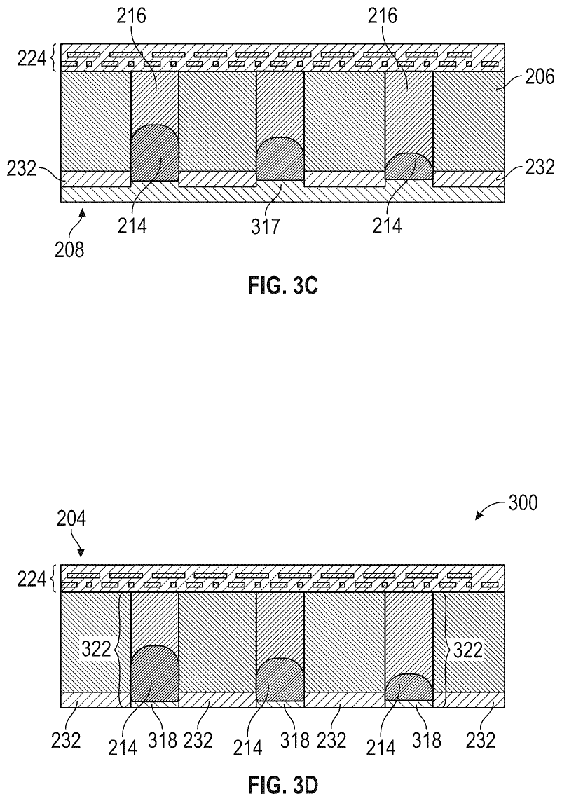

FIGS. 3A-3D schematically illustrate a method of forming a microelectronic structure 300 in accordance with another embodiment. The microelectronic structure 300 formed by this method (shown in FIG. 3D) is similar to the microelectronic structure 200 shown in FIG. 2G, except that the microelectronic structure 300 also has a bonding pad 318 or a conductive bonding layer disposed over the back side of the conductive tip portion 214 and embedded in the dielectric layer 232. FIG. 3A is similar to FIG. 2G.

FIG. 3B shows recesses 308 of the conductive tip portions 214 of FIG. 3A. This results in the partial removal of the tip portion 214. For example, the conductive tip portion 214 can be selectively etched relative to the surrounding dielectric layer 232. In other embodiments, the recesses 308 of the conductive tip portions 214 can be formed during planarization or CMP.

FIG. 3C shows the deposition of a conductive layer 317 over the back side 208 of the substrate 206 and over the back side of the TSV structures 222 (shown in FIG. 3B). The conductive layer 317 can comprise copper or another conductive material suitable for hybrid bonding. The conductive layer 317 can be deposited by using physical vapor deposition methods (sputtering, evaporation), CVD or ALD methods, or by using plating techniques, e.g., electroplating or electroless plating or combinations thereof. In other embodiments, a plurality of such conductive layers comprising a plurality of conductive materials or alloys may be deposited.

FIG. 3D shows the structure of FIG. 3C after being planarized to expose the bonding dielectric layer 232, leaving bonding pads 318 on the back sides of the conductive tip portions 214 of the TSV structures 322. The back side of the microelectronic structure 300 of FIG. 3D can be prepared for hybrid bonding, as described above. This microelectronic structure 300 is similar to the microelectronic structure 200 shown in FIG. 2G, except that the microelectronic structure 300 also has a bonding pad 318 disposed over the back side of the conductive tip portion 214 and embedded in the dielectric layer 232. In some embodiments, the bonding pad (e.g., bonding pad 318) can be the bottom-most feature of the TSV (e.g., TSV structure 322) and can work effectively in a TSV-to-pad DBI bonded structure. The dimensions for the bonding pad 318 were defined by the partial recess 308 of the conductive tip portion 214 in FIG. 3B, and thus may not employ a separate lithographic mask. The bonding pad 318 can comprise a different material (e.g., predominantly copper) from the conductive tip portion 214 (e.g., predominantly nickel). In some embodiments, the bonding pads may have a specific grain orientation (e.g. 111 grain orientation), nanostructures, or have certain impurity concentrations suitable for low temperature bonding. The skilled artisan will appreciate that the surface of the bonding pad 318 can be slightly recessed relative to the surface of the dielectric layer 232 surrounding it to facilitate metal bonding in an anneal/expansion phase of hybrid bonding, as described hereinabove. In some embodiments, a bonded structure (not shown) can be formed by direct bonding two elements similar to the structure shown in FIG. 3D. During direct bonding, the conductive tip of the bonding pad 318 of the TSV structure 322 at the back side of the first element (e.g. a first microelectronic structure 300) can be direct bonded to a contact pad or DBI pad formed on the front side or front surface of the second element (e.g. a second microelectronic structure 300), and the back surface of the first element can be direct bonded to the front surface of the second element without any adhesive.

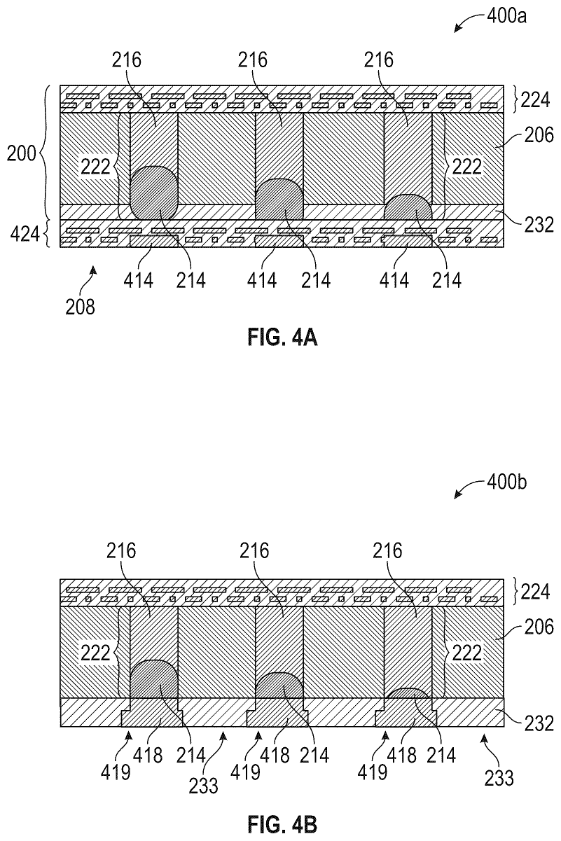

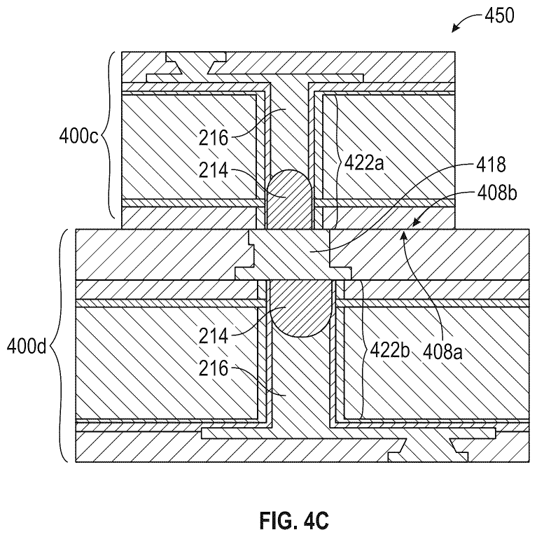

FIGS. 4A-4C present various configurations of microelectronic structures 400a, 400b and bonded structures 450. FIG. 4A shows a microelectronic structure 400a similar to the microelectronic structure 200 shown in FIG. 2G, with one or more RDL 424 formed over the back side 208 of the microelectronic structure 200 to electrically communicate between the conductive tip portion 214 of the TSV structures 222 and bond pads 414 in a bonding layer of the one or more RDL 424. Unlike microelectronic structures 200, 300 shown in FIG. 2G or FIG. 3D which enable TSV-to-pad hybrid bonded structures (for example, bonded structure 250 shown in FIG. 2H), the microelectronic structure 400a in FIG. 4A would enable pad-to-pad hybrid bonding. FIG. 4B shows a microelectronic structure 400b that has a bonding pad 418, similar to the one shown in FIG. 3D. The microelectronic structure 400b of FIG. 4B differs from the one of FIG. 3D in that the bonding pad 418 of the microelectronic structure 400b of FIG. 4B is wider than the TSV structure 222, and can be lithographically defined with masking and etching the dielectric layer 232, deposition of pad material (e.g., copper), and CMP. The conductive material of the bonding pad (e.g., bonding pads 414 of FIG. 4A or bonding pads 418 of FIGS. 4B-4C) may be the same or different from the material of the conductive tip portion 214. For example, if the conductive tip portion comprises nickel, the bonding pad may comprise copper. The skilled artisan will appreciate that the surface 419 of the bonding pad 418 can be slightly recessed relative to the surface 233 of the dielectric layer 232 surrounding it to facilitate metal bonding in an anneal/expansion phase of hybrid bonding, as described hereinabove.

FIG. 4C shows a hybrid bonded structure 450 according to some embodiments. The hybrid bonded structure 450 of FIG. 4C shows two microelectronic structures 400c, 400d hybrid bonded in a back-to-back configuration, i.e., the back side 408a of one microelectronic structure 400c with TSV structures 422a is hybrid bonded to the back side 408b of a second microelectronic structure 400d with TSV structures 422b. The electrical connection between the TSV structures 422a of the first microelectronic structure 400c and the TSV structures 422b of the second microelectronic structure 400d is shown as being through intermediate bonding pads 418 over the TSV conductive tip portions 214 of each microelectronic structure 400c, 400d.

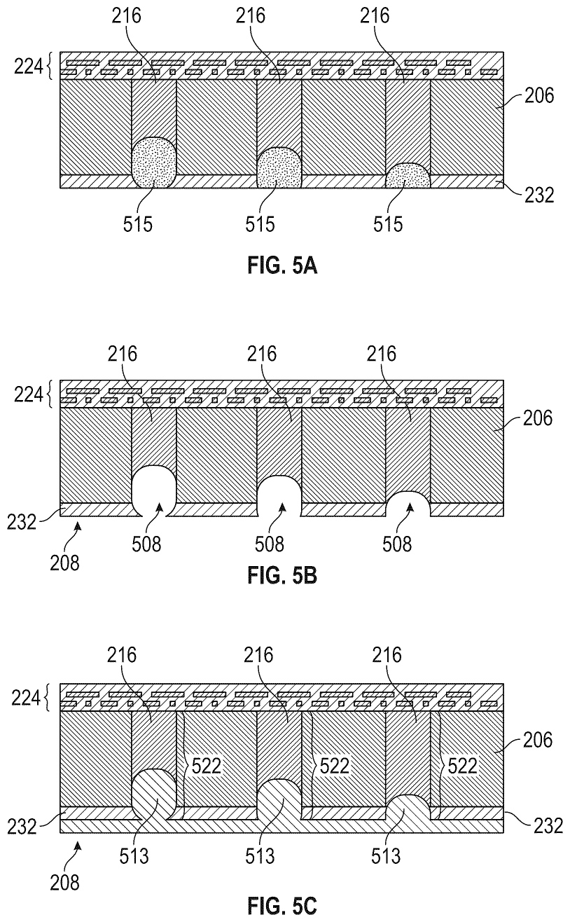

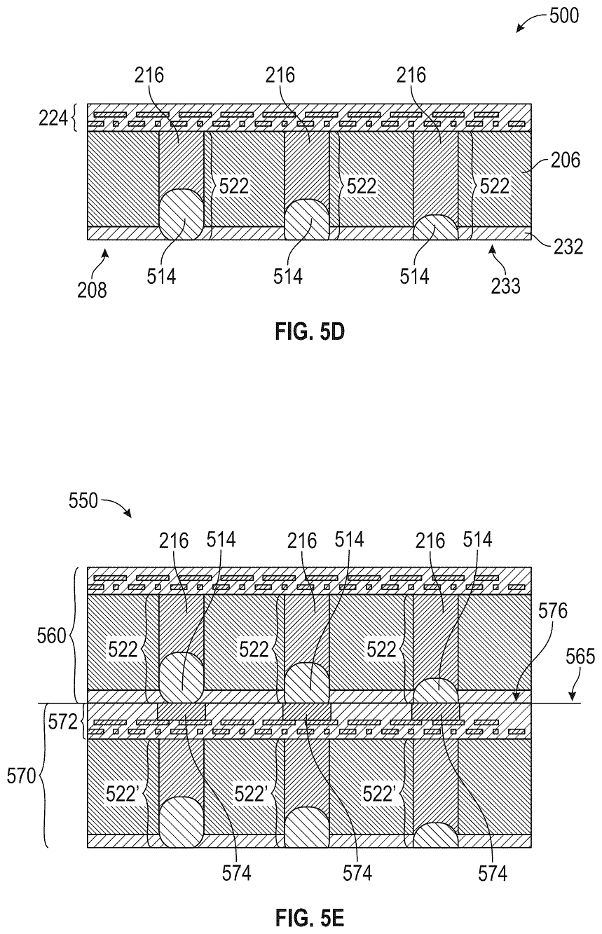

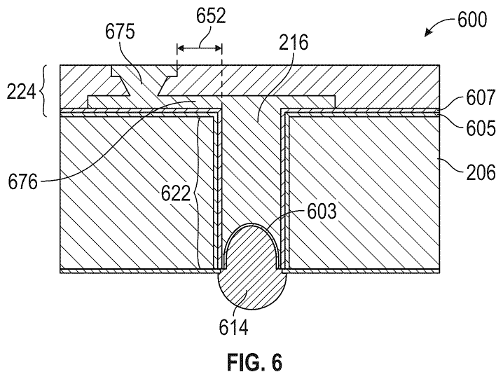

FIGS. 5A-5D schematically illustrate a method of forming a microelectronic structure 500 in accordance with another embodiment. The microelectronic structure 500 formed by this method (shown in FIG. 5D) is similar to the microelectronic structure 200 shown in FIG. 2G. However, the illustrated method employs a sacrificial tip portion 515 that is to be replaced with a conductive material (e.g., conductive layer 513 shown in FIG. 5C) after back side reveal, such that the resulting conductive tip portion 514 can have a different composition from that of the foregoing embodiments. FIG. 5A is similar to FIG. 2G, except the tip portion 214 shown in FIG. 2G is part of the final microelectronic structure 200, whereas the tip portion 515 shown in FIG. 5A is sacrificial (i.e., not part of the final microelectronic structure 500). A seed, barrier, and/or adhesion layer material (not shown) can also be provided between the sacrificial tip portion 515 of FIG. 5A and the second conductive via portion 216, similar to the barrier material 603 shown and discussed with respect to FIG. 6.

FIG. 5B shows the removal of the sacrificial material of the sacrificial tip portion 515 (shown in FIG. 5A). The sacrificial tip portion 515 (shown in FIG. 5A) is substantially removed from the microelectronic structure, forming a cavity 508 at the back end tip of the TSV structure 522 (shown in FIG. 5C). Like the tip portion 214 shown in FIG. 2E, the sacrificial tip portion 515 can comprise a material that is comparatively resistant to an etchant capable of etching the bulk substrate 206. In embodiments in which the bulk substrate 206 is silicon and the selective etchant is SF₆, the sacrificial tip portion 515 should comprise a material comparatively resistant to etching by SF₆ during the substrate etch back corresponding to FIG. 2E. The sacrificial tip portion 515 can comprise a material that is also selectively removable from the back side 208 of the structure without damaging the dielectric layer 232 (as shown in FIG. 5B). The material of the sacrificial tip portion 515 can also be selected such that it can be selectively removed relative to the second conductive via portion 216 above the sacrificial tip portion 515, although such constraint can also be omitted, particularly where a barrier material (not shown) is provided between the sacrificial tip portion 515 and the second conductive via portion 216. For example, the sacrificial tip portion 515 can comprise an organic material; for example, polyimide (PI), Polybenzoxazoles (PBO), Benzocyclobutene (BCB) based polymers, etc. An example selective etching comprises selective plasma etching or wet etching the organic materials, which can selectively remove a sacrificial material comprising organic materials like PI, PBO, BCB, etc. with minimal damage to surrounding materials exposed to the etch (e.g., silicon, silicon oxide, metal nitride and copper). In some embodiments, the sacrificial tip portion may comprise a polymeric material and can vaporize upon heating under vacuum at temperatures lower than 400° C. or temperatures lower than 300° C. Use of a barrier (not shown) between the sacrificial tip portion 515 and the second conductive via portion 216 will generally expand available selective etch chemistries for removal of the sacrificial material. In some embodiments, inorganic materials may also be used as the sacrificial material at the bottom of the TSV tip; for example, silicon oxide. In some embodiments, back side thinning comprising lapping, grinding, and polishing from the back side of the structure may continue until the bottom tips of all the TSV structures are exposed. The sacrificial material may be selected such that exposing the bulk substrate 206 during thinning to these sacrificial material will not contaminate (e.g. via diffusion) the bulk substrate 206.

In some embodiments, the removal of the sacrificial material exposes a barrier (not shown) previously disposed between the sacrificial tip portion 515 and the second conductive via portion 216. In some embodiments, the removal of the sacrificial material exposes the second conductive via portion 216 at the back side 208 of the substrate 206.

FIG. 5C shows the deposition of a conductive layer 513 over the back side 208 of the substrate and over the back side of the TSV structures 522. The conductive layer 513 backfills the cavity 508 formed by the removal of the sacrificial tip portion 515 of the TSV structure 522, replacing the sacrificial material. In some embodiments, another conductive barrier layer and/or seed layer (not shown) may be deposited on the exposed back side of the second conductive via portion of the TSV structure before the conductive layer is deposited over the back side of the substrate. In some embodiments, the conductive layer 513 comprises copper, copper alloys, nickel, nickel alloys, tungsten, and/or indium, or another metal able to be direct bonded to copper. In some embodiments, the conductive layer 513 is predominantly copper, as described with respect to the second conductive portion. The conductive layer 513 can be deposited using plating techniques, e.g., electroplating or electroless plating.

FIG. 5D shows the structure of FIG. 5C after being planarized to expose the dielectric layer 232. The back side 208 of the microelectronic structure 500 of FIG. 5D can be prepared for hybrid bonding, as described above. The skilled artisan will appreciate that the surface of the (replacement) conductive tip portion 514 can be slightly recessed relative to the surface 233 of the dielectric layer 232 surrounding it to facilitate metal bonding in an anneal/expansion phase of hybrid bonding, as described hereinabove.

The microelectronic structure 500 of FIG. 5D is similar to the microelectronic structure 200 shown in FIG. 2G, but one difference between them is that the conductive tip portion 514 of FIG. 5D can be more similar in composition to the second conductive via portion 216 of FIG. 5D. Although the two portions of the TSV structure 522 can both have similar compositions, e.g., predominantly copper, they are deposited at different stages and may have used different processes. For example, the second conductive via portion 216 is deposited at a stage corresponding to FIG. 2C into very deep and high aspect ratio openings, whereas the conductive tip portions 514 are deposited at the stage of FIG. 5C into much shallower recesses (e.g., between 0.5 μm and 10 μm). The skilled artisan will appreciate that, accordingly, even if both portions 514, 216 have similar copper content, they can have different levels of impurities due to different additives during deposition, and/or they can have different crystal structures (e.g., different average grain sizes or orientations) from one another, such that the two portions 514, 216 can be distinguished from one another in the final structures in some embodiments. In some embodiments, the conductive tip portion may have a specific grain orientation (e.g. 111 grain orientation), nanostructures, or have certain impurity concentrations suitable for low temperature bonding to a conductive feature of another element without any intervening adhesive (e.g. direct bonding, explained above). Additionally, a barrier layer and/or seed layer (not shown) can intervene between the conductive tip portion 514 and the second conductive via portion 216 in some embodiments.

FIG. 5E shows a bonded structure 550, in which the back side of a first element 560 (e.g., a first microelectronic structure 500 of FIG. 5D) is hybrid bonded to BEOL or RDL 572 on the front side 576 of a second element 570 (e.g., another microelectronic structure 500 like that of FIG. 5D), along a bond interface 565. In some embodiments, the conductive tip portion 514 of the TSV structure 522 at the back side of the first element 560 is direct bonded to a contact pad 574 on the front surface or front side 576 of the second element 570. In some embodiments, the TSV structure 522 of the first element 560 is in electrical communication with the TSV structure 522′ of the second element 270. In some embodiments, the metal-to-metal bond between the first and second elements 560, 570 is a copper-to-copper direct bond.

FIG. 6 shows an additional aspect of a microelectronic structure 600. FIG. 6 is similar to FIG. 2G, except that the conductive tip portion 614 of the microelectronic structure 600 shown in FIG. 6, which can be formed at the stages of FIG. 2B or 5C, comprises a conductive adhesive, such as solder. While the microelectronic structure 200 shown in FIG. 2G is configured to adhere to a second element through hybrid bonding without an intervening adhesive, the microelectronic structure 600 shown in FIG. 6 is configured to adhere to a second element by more conventional techniques. The microelectronic structure 600 shown in FIG. 6 can be formed using the same method as the one shown in FIGS. 2A-2G, or by the sacrificial process of FIGS. 5A-5D, except the conductive tip portion 614 comprises a conductive adhesive. Additionally, in the illustrated embodiment of FIG. 6, the TSV structure 622 of the microelectronic structure 600 has an optional lateral offset 652 relative to a bonding pad 675, which is in electrical communication with the TSV structure 622 by way of a conductive trace 676.

FIG. 6 also shows an optional barrier material 603 intervening between the conductive tip portion 614 and the second conductive via portion 216. The barrier material 603 can be a conductive barrier, such as tungsten or various transition metal nitrides, and can be deposited between the stages corresponding to those shown in FIG. 2B and FIG. 2C. FIG. 6 also shows optional barrier layers 605 and seed layers 607 intervening between the TSV structure 622 and the bulk substrate 206.

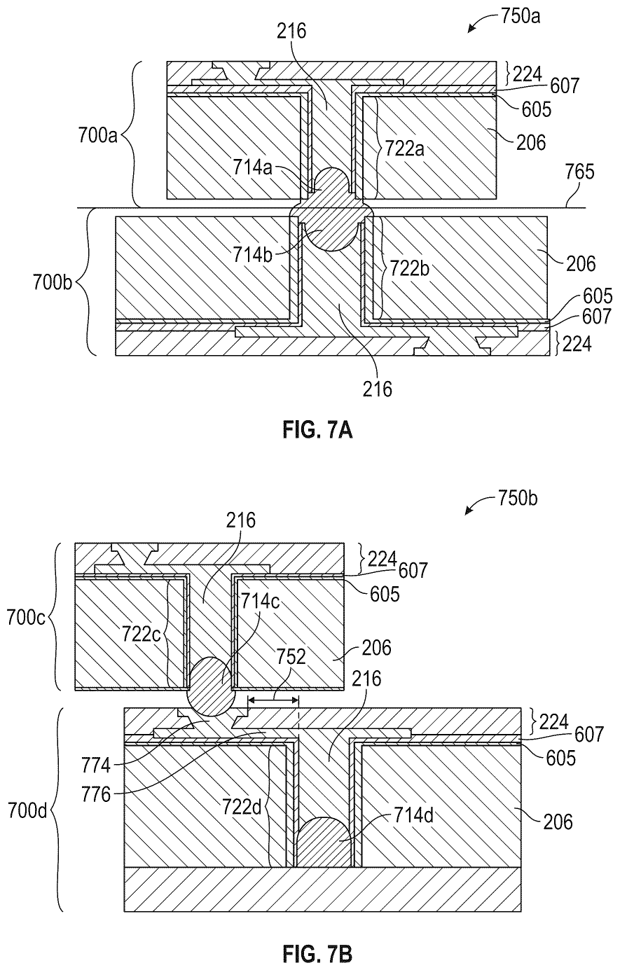

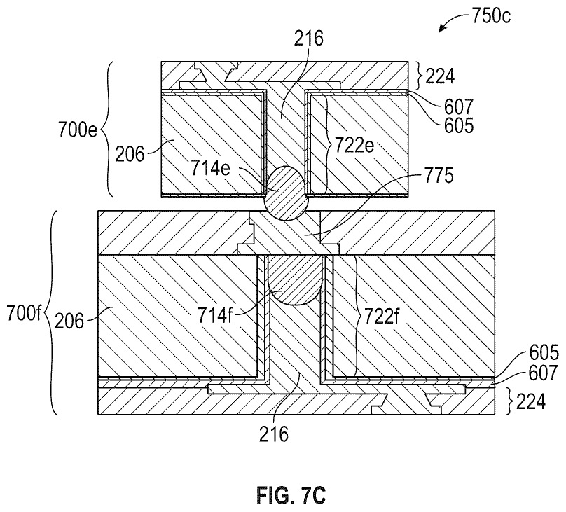

FIGS. 7A-7C present various schematics of bonded structures 750a-c comprising microelectronic structures 700a-f with TSV structures 722 similar to those of FIGS. 2G, 3D, 4B, 5D except that, like FIG. 6, the microelectronic structures 700a-f need not be prepared for hybrid bonding. The two microelectronic structures 700 shown in each of FIGS. 7A-7C are bonded together in more conventional metal-to-metal configurations, rather than by direct bonding. In some embodiments, the first and second microelectronic structures 700 shown in FIGS. 7A-7C are bonded by thermocompression bonding or soldering.

In FIG. 7A, two microelectronic structures 700a, 700b—each similar to the one shown in FIG. 6—are bonded in a back-to-back configuration to form a bonded structure 750a. The conductive tip portion 714a on the back side of the TSV structure 722a of one microelectronic structure 700a is metal-to-metal bonded to the conductive tip portion 714b on the back side of the TSV structure 722b of a second microelectronic structure 700b. The conductive tip portions 714a, 714b can comprise solder, as described with respect to FIG. 6. In other embodiments, the contacts at the bond interface 765 can include copper bumps or pillars provided after the conductive tip portions 714 are revealed (e.g., FIG. 2D) or after or during the replacement of sacrificial tip portions 515 with conductive tip portions 514 (e.g., as shown in FIGS. 5A-5D).

FIG. 7B shows a microelectronic structure 700c having a TSV structure 722c including a conductive tip portion 714c and a differently composed second conductive via portion 216, as described for embodiments above, bonded in a back-to-front configuration to a second microelectronic structure 700d, to form a bonded structure 750b. The conductive tip portion 714c on the back side of the TSV structure 722c of one microelectronic structure 700c is bonded directly or by way of an intervening bump or pillar to the metallization layer(s) 224 (e.g. BEOL or RDL layer(s)) of the second microelectronic structure 700d. The second microelectronic structure 700d includes a TSV structure 722d, which itself includes a conductive tip portion 714d. In the illustrated embodiment of FIG. 7B, the TSV structure 722c of the first microelectronic structure 700c has a lateral offset 752 relative to the TSV structure 722d of the second microelectronic structure 700d. The conductive tip portion 714c on the back side of the TSV structure 722c of one microelectronic structure 700c is bonded to an intervening contact pad 774 of the second microelectronic structure 700d, which is in electrical communication with the TSV structure 722d of the second microelectronic structure 700d, by way of a conductive trace 776.

FIG. 7C shows a microelectronic structure 700e having a TSV structure 722e including a conductive tip portion 714e and a differently composed second conductive via portion 216, as described for embodiments above, bonded in a back-to-back configuration to a second microelectronic structure 700f, to form a bonded structure 750c. The conductive tip portion 714e on the back side of the TSV structure 722e of one microelectronic structure 700e is bonded to an intervening contact pad 775 of the second microelectronic structure 700f, which is in electrical communication with the TSV structure 722f of the second microelectronic structure 700f.

In one aspect, a microelectronic structure includes a first element and a through substrate via (TSV) structure. The first element includes a bulk portion having a front side and a back side opposite the front side. The TSV structure is disposed in an opening extending at least partially through the bulk portion from the front side to the back side. The TSV structure includes a conductive tip portion and a second conductive via portion. The second conductive via portion is disposed between the front side and the conductive tip portion. The conductive tip portion contains a different conductive material than the second conductive via portion.

In some embodiments, the back side of the first element is prepared for hybrid bonding. In some embodiments, the conductive tip portion includes a material less susceptible than copper to smearing during chemical mechanical polishing (CMP). In some embodiments, the second conductive via portion is predominantly copper. In some embodiments, the conductive tip portion includes nickel. In some embodiments, the conductive tip portion is predominantly nickel. In some embodiments, the conductive tip portion includes indium. Some embodiments further include a dielectric layer disposed on the back side of the bulk portion. In some embodiments, the TSV structure further includes a bonding pad disposed over the back side of the conductive tip portion, and the bonding pad is embedded in the dielectric layer. In some embodiments, the bonding pad is predominantly copper. In some embodiments, the bonding pad is recessed relative to the dielectric layer. In some embodiments, the conductive tip portion is recessed relative to the dielectric layer. In some embodiments, the first element includes a plurality of TSV structures, in which a thickness of a conductive tip portion of one TSV structure of the plurality is different from a thickness of a conductive tip portion of another TSV structure of the plurality by more than 1%. Some embodiments further include a barrier layer and/or a seed layer disposed along at least a portion of an interface between the TSV structure and bulk portion. Some embodiments further include a second element hybrid bonded to the back side of the first element.

In another aspect, a method of forming a microelectronic structure includes providing a plurality of via structures in a bulk substrate material. Each of the via structures are disposed in a blind opening extending partially through the bulk substrate from a front side of the bulk substrate material toward a back side of the bulk substrate material. Each via structure includes a tip portion in the blind opening and a conductive second via portion disposed in the blind opening between the front side and the tip portion. The second via portion includes a material different from that of the tip portion. The method also includes revealing the tip portion of the plurality of via structures from the back side.

In some embodiments, the method further includes preparing the back side for hybrid bonding. In some embodiments, preparing the back side for hybrid bonding includes etching back the bulk substrate from the back side, causing the conductive tip portions to protrude from the bulk substrate. In such embodiments, preparing the back side for hybrid bonding further includes depositing a dielectric bonding layer over and around the tip portions after etching back, and polishing the dielectric bonding layer to reveal the tip portions. In some embodiments, providing the plurality of via structures includes filling bottom portions of the blind openings with a bottom-up deposition process to form the tip portions in the bottom portions and voids extending the blind openings from the tip portions to the front side of the bulk substrate material. In such embodiments, providing the plurality of via structures further includes depositing the second via portion into the voids. Some embodiments further include etching the back side of the bulk substrate material such that the tip portion of the via structures protrudes from the bulk substrate material. In some embodiments, the tip portion of the via structures protrudes from the bulk substrate material by less than 100 nm. Some embodiments further include depositing a dielectric layer over the back side of the bulk substrate and over the protruding via structures. Some embodiments further include planarizing the dielectric layer to reveal the tip portion of the via structures from the back side. Some embodiments further include disposing bonding pads over the back side of the tip portions. In such embodiments, the bonding pads are embedded in the dielectric layer, and the tip portions are electrically conductive. In some embodiments, the second via portion is predominantly copper. In some embodiments, the tip portion is electrically conductive. In some embodiments, the tip portion is predominantly nickel. In some embodiments, the tip portion comprises a sacrificial material. Such embodiments further include, after revealing the tip portion, selectively removing and replacing the sacrificial material with an electrically conductive tip portion. Some embodiments further include hybrid bonding the microelectronic structure to a second element.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A microelectronic structure comprising:
a first element comprising a bulk portion having a front side and a back side opposite the front side; and
a through substrate via (TSV) structure disposed in an opening extending at least partially through the bulk portion from the front side to the back side, the TSV structure comprising:
a conductive tip portion and a second conductive via portion, the second conductive via portion disposed between the front side and the conductive tip portion, the conductive tip portion containing a different conductive material than the second conductive via portion.

2. The microelectronic structure of claim 1, wherein the back side of the first element is prepared for hybrid bonding.

3. The microelectronic structure of claim 1, wherein the conductive tip portion comprises a material less susceptible than copper to smearing during chemical mechanical polishing (CMP).

4. The microelectronic structure of claim 3, wherein the second conductive via portion is predominantly copper.

5. The microelectronic structure of claim 4, wherein the conductive tip portion comprises nickel.

6. (canceled)

7. The microelectronic structure of claim 4, wherein the conductive tip portion comprises indium.

8. The microelectronic structure of claim 1, further comprising a dielectric layer disposed on the back side of the bulk portion, wherein the conductive tip portion is recessed relative to the dielectric layer.

9. (canceled)

10. (canceled)

11. (canceled)

12. (canceled)

13. The microelectronic structure of claim 1, wherein the first element comprises a plurality of TSV structures, wherein a thickness of a conductive tip portion of one TSV structure of the plurality is different from a thickness of a conductive tip portion of another TSV structure of the plurality by more than 1%.

14. The microelectronic structure of claim 1, further comprising a barrier layer and/or a seed layer disposed along at least a portion of an interface between the TSV structure and bulk portion.

15. The microelectronic structure of claim 1, further comprising a second element hybrid bonded to the back side of the first element.

16. A method of forming a microelectronic structure, the method comprising:
providing a plurality of via structures in a bulk substrate material, each of the via structures disposed in a blind opening extending partially through the bulk substrate from a front side of the bulk substrate material toward a back side of the bulk substrate material, each via structure comprising:
a tip portion in the blind opening, and
a conductive second via portion disposed in the blind opening between the front side and the tip portion, wherein the second via portion comprises a material different from that of the tip portion; and
revealing the tip portion of the plurality of via structures from the back side.

17. The method of claim 16, further comprising preparing the back side for hybrid bonding.

18. The method of claim 17, wherein preparing the back side for hybrid bonding comprises:
etching back the bulk substrate from the back side, causing the conductive tip portions to protrude from the bulk substrate;
depositing a dielectric bonding layer over and around the tip portions after etching back; and
polishing the dielectric bonding layer to reveal the tip portions.

19. The method of claim 16, wherein providing the plurality of via structures comprises:
filling bottom portions of the blind openings with a bottom-up deposition process to form the tip portions in the bottom portions and voids extending the blind openings from the tip portions to the front side of the bulk substrate material; and
depositing the second via portion into the voids.

20. The method of claim 19, further comprising etching the back side of the bulk substrate material such that the tip portion of the via structures protrudes from the bulk substrate material.

21. The method of claim 20, wherein the tip portion of the via structures protrudes from the bulk substrate material by less than 100 nm.

22. The method of claim 20, further comprising:
depositing a dielectric layer over the back side of the bulk substrate and over the protruding via structures; and
planarizing the dielectric layer to reveal the tip portion of the via structures from the back side.

23. (canceled)

24. (canceled)

25. The method of claim 19, wherein the second via portion is predominantly copper.

26. The method of claim 19, wherein the tip portion is electrically conductive.

27. (canceled)

28. (canceled)

29. The method of claim 16, further comprising hybrid bonding the microelectronic structure to a second element.
